(19) United States
(12) Patent Application Publication
(10) Pub. No.: US 2009/0315121 A1
(43) Pub. Date: Dec. 24, 2009

(54) STABLE STRESS DIELECTRIC LAYER

(75) Inventors: Luona GOH, Singapore (SG); Jeff Jiehui SHU, Singapore (SG); Huang LIU, Singapore (SG); Wei LU, Singapore (SG)

Correspondence Address: HORIZON IP PTE LTD, 7500A Beach Road, #04-306/308 The Plaza, SINGAPORE 199591, SG

(73) Assignee: Chartered Semiconductor Manufacturing, Ltd., Singapore (SG)

(21) Appl. No.: 12/141,932

(22) Filed: Jun. 19, 2008

(51) Int. Cl. H01L 29/78; H01L 21/31

(52) U.S. Cl. 257/396; 257/288; 438/778; 257/E21.24

(57) ABSTRACT

An integrated circuit is provided having a substrate and a transistor in an active region of the substrate. The substrate also has an isolation region having a dielectric material. In one embodiment, a pre-metal dielectric (PMD) layer is disposed over the substrate and the transistor. At least one of the isolation region or the PMD layer includes O₃-TEOS having a first stress. A cap layer is disposed over the O₃-TEOS in the isolation region or the PMD layer. The cap layer prevents degradation of the first stress of the O₃-TEOS.

### FIELD OF THE INVENTION

The present invention relates generally to integrated circuits (ICs), and more particularly to forming stressed dielectric layers in ICs.

### BACKGROUND OF THE INVENTION

Integrated circuits (ICs) typically comprise numerous circuit components interconnected to perform the desired functions. Such circuit components include, for example, transistors such as field effect transistors (FETs). Dielectric materials have been employed to generate strain in the channel region of the transistor to enhance carrier mobility.

It is desirable to provide enhanced strain generation in channel regions of transistors to enhance carrier mobility.

### SUMMARY OF THE INVENTION

The present invention relates to forming stressed dielectric layers. In one aspect, a device comprises a substrate having isolation regions. The isolation regions comprise isolation material which has a first stress. A cap layer disposed on the isolation material, wherein the cap layer reduces degradation of the first stress.

In another embodiment, an integrated circuit (IC) comprises a transistor disposed on a substrate. A dielectric layer is disposed on the substrate over the transistor, the dielectric layer comprises a first stress. A cap layer is disposed on the dielectric layer, wherein the cap layer reduces degradation of the first stress.

In yet another aspect, a method of fabricating a device is disclosed. The method includes providing a substrate prepared with isolation regions with an isolation material having a first stress. A cap layer is formed on the isolation material in the isolation regions, wherein the cap layer reduces degradation of the first stress.

In another embodiment, a method of fabricating an IC is disclosed. The method includes providing a substrate. A dielectric layer is formed on the substrate. The dielectric layer comprises a first stress. A cap layer is formed on the dielectric layer, wherein the cap layer reduces degradation of the first stress.

These and other objects, along with advantages and feature of the present invention herein disclosed, will become apparent through reference to the following description and the accompanying drawings. Furthermore, it is to be understood that the features of the various embodiments described herein are not mutually exclusive and can exist in various combinations and permutations.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. In the following description, various embodiments of the present invention are described with reference to the following drawings, in which:

FIG. 1 shows a cross-section of a portion of an IC in accordance with one embodiment of the invention;

FIG. 2 shows a cross-section of a portion of an IC in accordance with another embodiment of the invention;

FIGS. 3a-e show a process for forming an IC in accordance with one embodiment of the invention;

FIGS. 4a-b show a process for forming an IC in accordance with another embodiment of the invention; and

FIG. 5 shows the chemical reactions that occur during a chemical vapor deposition (CVD) process to form a N doped O₃-TEOS oxide film, in accordance with one embodiment of the reaction.

### DETAILED DESCRIPTION OF THE INVENTION

The present invention relates generally to semiconductor devices or ICs. More particularly, the present invention relates to stressed dielectric layers for strain generation in, for example, the channel region of a transistor. The invention can be applied to various types of ICs, such as memory devices including dynamic random access memories (DRAMs), static random access memories (SRAMs), non-volatile memories including programmable read-only memories (PROMs) and flash memories, optoelectronic devices, logic devices, communication devices, digital signal processors (DSPs), microcontrollers, system-on-chip, as well as other types of devices. The ICs can be incorporated in various types of products. Such products, for example, include cell phones, personal digital assistants, computers or other electronic products.

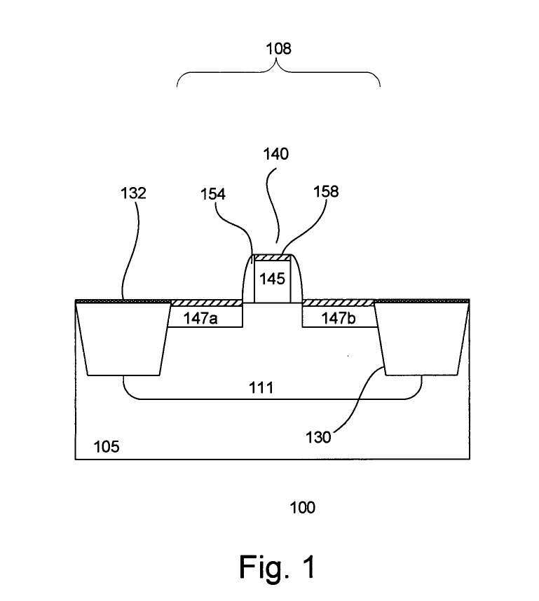

FIG. 1 shows a cross-sectional view of a portion of an IC 100 in accordance with one embodiment of the invention. The IC comprises a substrate 105. The substrate comprises a semiconductor material, such as silicon. Other types of semiconductor substrates are also useful. Defined on the substrate is an active region 108. The active region includes a doped well 111 of a first charge carrier type. In one embodiment, the first charge carrier type comprises p-type. For example, the doped well comprises p-type dopants such as boron (B), aluminum (Al) or a combination thereof.

A transistor 140 is disposed in the active region. The transistor, for example, comprises a FET. The FET comprises a second charge carrier type. In one embodiment, the second charge carrier type comprises n-type. The transistor includes a gate stack 145. The gate stack can be gate conductor which forms a plurality of transistors having a common gate. The gate stack comprises a gate electrode over a gate dielectric. The gate electrode, for example, comprises polysilicon while the gate dielectric comprises silicon oxide. Other types of gate electrode and gate dielectric materials are also useful. Dielectric spacers 154 are typically provided on sidewalls of the gate stack.

Beneath the gate is a channel region of the transistor. First and second diffusion regions 147a-b are provided adjacent to the gate stack, separated by the channel region. The diffusion regions comprise second type or n-type dopants, such as phosphorus (P), arsenic (As), antimony (Sb) or a combination thereof. Silicide contacts 158 can be provided on the top of the gate and diffusion regions to reduce sheet resistance.

Isolation regions 130 are provided to isolate the active region from other device regions. The isolation regions, for example, comprise shallow trench isolations (STIs). STIs comprise trenches formed in the substrate and filled with a dielectric material. The isolation regions are used to isolate active device regions on the substrate. The depth of the STIs is generally about 1500-4500 Å. Other depths are also useful. The doped well typically overlaps the bottom of the STIs.

In one embodiment, the dielectric material filling the STIs induces a first stress on the channel region of the transistor. Inducing a first stress in the channel region improves the performance of the transistor. In one embodiment, the first stress comprises a tensile stress to improve the performance of the transistors. For example, the first stress improves the performance of n-type and p-type transistors.

The dielectric material, in a preferred embodiment, comprises an ozone-tetraethoxysilane (O₃-TEOS) oxide. The O₃-TEOS, for example, induces a tensile stress in the channel region of the transistor. To form the O₃-TEOS, subatmospheric chemical vapor deposition (SACVD) can be employed. Other techniques are also useful.

In accordance with one embodiment of the invention, a cap layer 132 is provided on the STI trenches. The cap layer acts as a barrier layer to retard moisture absorption by the dielectric material filling the STIs, which can lead to stress degradation. The cap layer, for example, comprises a dielectric material which prevents or absorbs moisture.

In one embodiment, the cap layer comprises a doped O₃-TEOS oxide. Preferably, the cap layer is formed from materials filling the trench. For example, the cap layer can be provided by treating the surface of the dielectric material filling the STIs. For example, dopant species are absorbed at the surface of the STI fill to form the cap layer. The dopant species, in one embodiment, comprises nitrogen (N). Other dopant species such as NH₃, N₂O, NO₂, NCl₃, NF₃, I₃N and N₂O₃ may also be useful. The concentration of dopants in the STI cap layer should be sufficient to enable the cap layer to retard moisture absorption by the STI dielectric. In one embodiment, the N dopant concentration in the STI cap layer is about 1E6-1E15 c/s (using SIMs measurement), and preferably about 1E10 c/s. Other concentrations are also useful. In general, the higher the N concentration in the O₃-TEOS, the higher its resistance to moisture absorption, and the more stable its stress. The STI cap layer should be sufficiently thick to act as an effective moisture barrier. In one embodiment, the thickness of the STI cap layer is about 100-4000 Å, and preferably about 200-1000 Å. Other thicknesses are also useful.

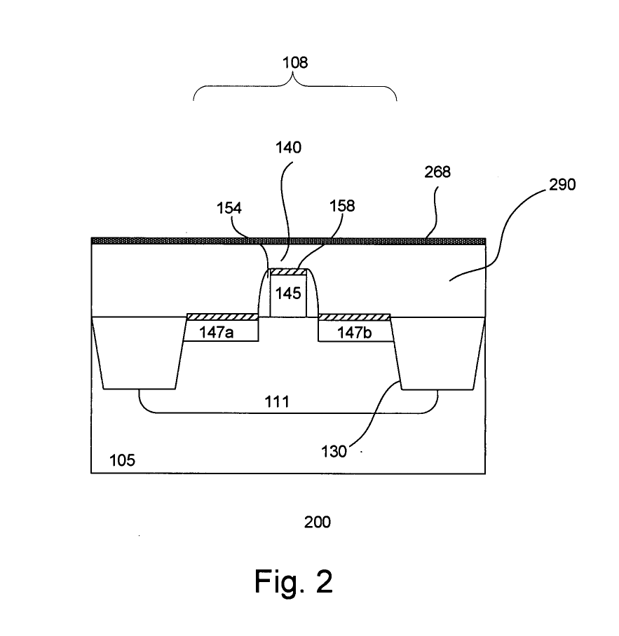

FIG. 2 shows a cross-sectional view of a portion of an IC 200 in accordance with another embodiment of the invention. The portion is similar to the portion shown in FIG. 1. For example, the portion includes a substrate 105 with a transistor 140 formed thereon. Isolation regions 130 are provided to isolate the active region of the transistor from other devices. A stress liner (not shown) can be provided over the transistor to introduce a stress in the channel region, so as to improve the performance thereof. For example, a tensile stress liner can be provided to improve the performance of a n-type transistor, while in the case of a p-type transistor, a compressive stress liner may be used. For the case where the IC comprises both n-type and p-type transistors, a dual stress liner (DSL) can be provided.

A pre-metal dielectric (PMD) 290 layer is provided over the substrate, covering the transistor and the isolation regions. The PMD layer comprises a dielectric material. The PMD layer, for example, is about 400-6000 Å thick. Other thicknesses are also useful.

In one embodiment, the PMD layer induces a first stress on the channel region of the transistor. In one embodiment, the first stress comprises a tensile stress to improve performance of n-type transistors. The dielectric material, in a preferred embodiment, comprises O₃-TEOS oxide. The O₃-TEOS oxide can be deposited by SACVD. Other techniques are also useful.

In accordance with one embodiment of the invention, a PMD cap layer 268 is provided over the PMD layer. The PMD cap layer acts as a barrier layer to retard moisture absorption by the PMD layer which can lead to stress degradation. In one embodiment, the PMD cap layer comprises a dielectric cap layer similar to the cap layer which covers the STIs as described in FIG. 1. For example, the cap layer comprises a barrier dielectric layer which includes a doped O₃-TEOS such as N-doped O₃-TEOS. The doped O₃-TEOS can be provided by treating the surface of the PMD layer. For example, dopant species are absorbed at the surface of the PMD layer, forming the cap layer. The dopant species, in one embodiment, comprises nitrogen (N). Other dopant species such as NH₃, N₂O, NO₂, NCl₃, NF₃, T₃N and N₂O₃ may also be useful. The concentration of dopants in the PMD cap layer should be sufficient to enable the cap layer to retard moisture absorption by the PMD layer. In one embodiment, the N dopant concentration in the PMD cap layer is about 1E6-1E15 c/s (using SIMs measurement), and preferably about 1E10 c/s. Other concentrations are also useful. In general, the higher the N concentration in the O₃-TEOS, the higher its resistance to moisture absorption, and the more stable its stress. The PMD cap layer should be sufficiently thick to act as an effective moisture barrier. In one embodiment, the thickness of the PMD cap layer is about 100-4000 Å, and preferably about 200-1000 Å. Other thicknesses are also useful.

Alternatively, the PMD cap layer comprises a silicon nitride layer. The thickness of the silicon nitride layer can be about 100-4000 Å or about 200-1000 Å. Other thicknesses are also useful. The silicon nitride layer, in one embodiment, comprises a stressed silicon nitride layer. Preferably, the silicon nitride layer comprises a tensile stress silicon nitride layer.

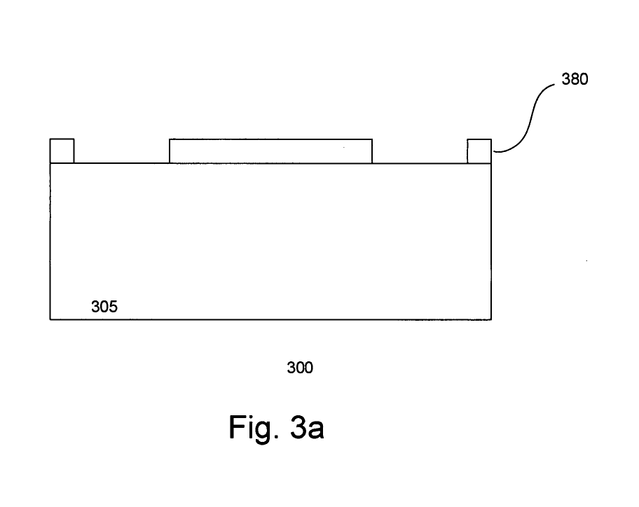

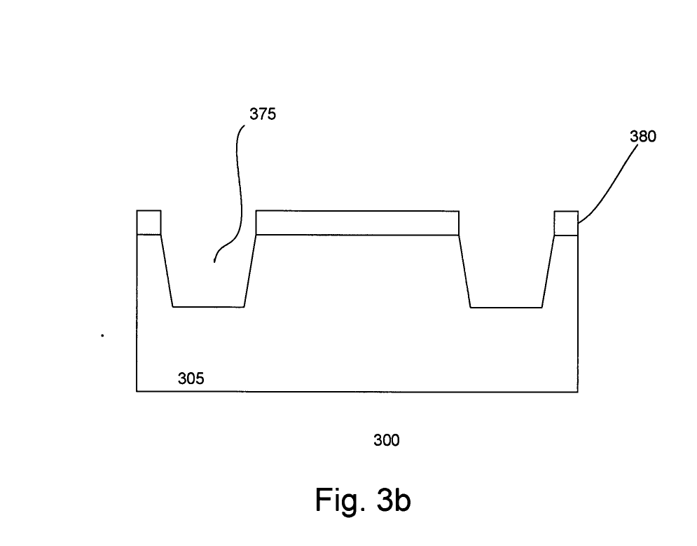

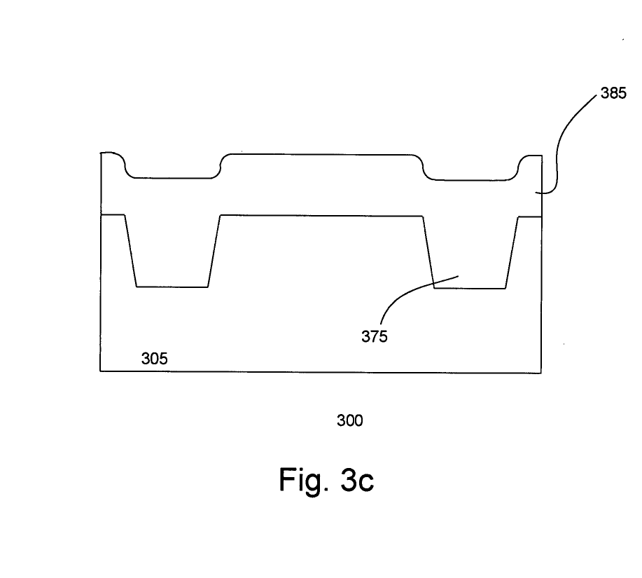

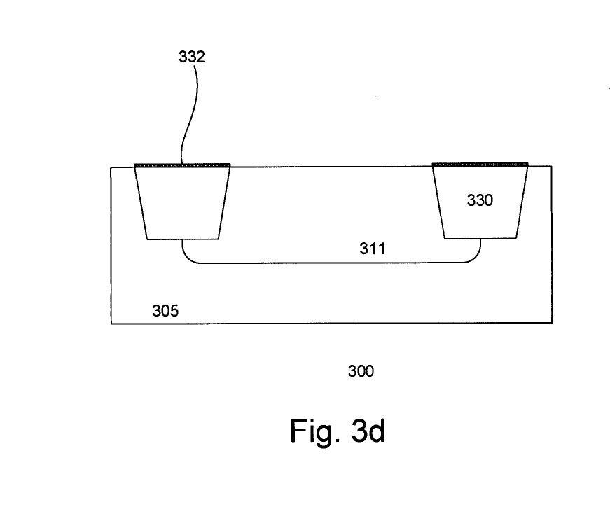

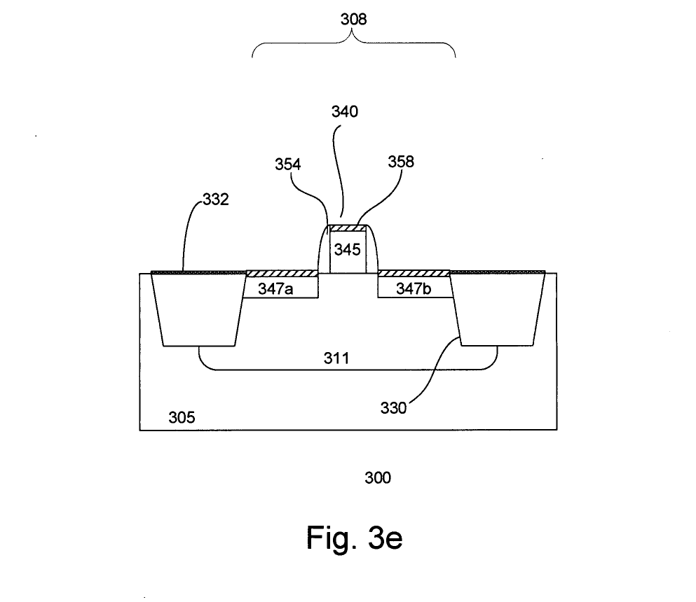

FIGS. 3a-e show a process for forming an IC 300 in accordance with one embodiment of the invention. Referring to FIG. 3a, a substrate 305 is provided. The substrate, in one embodiment, comprises a p-type silicon substrate. Other types of substrates, such as a germanium-based, gallium arsenide, silicon-on-insulator (SOI), or sapphire substrate, are also useful.

A mask 380 is formed on the surface of the substrate. The mask is patterned to form openings corresponding to locations where STI trenches are to be formed. The mask, for example, comprises a soft mask such as photoresist. The photoresist can be patterned by conventional lithographic techniques. An antireflective coating (ARC) is typically provided beneath the photoresist.

Preferably, the mask comprises a hard mask and a soft mask. The hard mask can include a pad oxide layer under a silicon nitride layer. Other types of hard masks are also useful. An ARC can be disposed between the hard mask and soft mask. The soft mask is patterned using conventional lithographical techniques to form openings. The soft mask is then used to pattern the hard mask using, for example, an anisotropic etch such as reactive ion etching (RIE). The soft mask can be removed after patterning the hard mask.

Referring to FIG. 3b, the substrate is etched to form trenches 375 in regions unprotected by the mask. The trenches are etched using, for example, reactive ion etching (RIE). Other processes for forming the trenches are also useful. Typically, the depth of the trenches is about 1500-4500 Å. Other depths are also useful and may depend on design requirements.

Referring to FIG. 3c, a dielectric layer 385 is deposited on the substrate to fill the trenches. The dielectric layer is sufficiently thick to ensure complete filling of the trenches. A dielectric liner layer (not shown) can be formed to line the substrate and trenches prior to depositing the dielectric layer. The liner layer, for example, comprises silicon nitride which serves as a polish stop.

The dielectric layer, in one embodiment, comprises a dielectric material which applies a first stress. The dielectric material, in one embodiment, applies a tensile stress. Preferably, the dielectric material comprises high tensile O₃-TEOS. Other types of dielectric materials are also useful. In one embodiment, the O₃-TEOS oxide is formed by a conventional SACVD process. Other types of processes are also useful. The O₃-TEOS oxide film, in one embodiment, has a tensile stress of about 0.2-3.5 G dyne/cm².

The process continues to form a cap layer 332. The cap layer acts as a barrier to prevent moisture absorption by the dielectric material, thereby retarding tensile stress degradation thereof. The cap layer, in one embodiment, comprises an upper portion of the dielectric layer.

In one embodiment, forming the cap layer comprises subjecting the substrate to a thermal treatment with a dopant source. The thermal treatment can comprise microwave, UV curing treatment or rapid thermal anneal (RTA). Other types of thermal treatment are also useful. The dopant source, in one embodiment, comprises nitrogen. The nitrogen dopant source, for example, comprises N₂, NH₃ or a combination thereof. Other types of dopant sources for nitrogen, such as NO₂, NCl₃, NF₃, T₃N and N₂O₃, are also useful. Furthermore a combination of nitrogen sources is also useful.

The thermal treatment serves to drive out moisture from the dielectric material. Preferably, the thermal treatment reduces the water content of the dielectric material to about 0.01-5 wt %. Additionally, the thermal treatment causes the dopants to react with the upper portion of the dielectric layer to form a N-doped cap layer. The dopant concentration of the cap layer is preferably about 1E6-1E15 c/s (using SIMS measurement). The thickness of the cap layer is about 100-4000 Å below the surface of the substrate in the trenches. For a microwave thermal treatment, it can be performed at about HRF 300-1000 W. For a RTA thermal treatment, it can be performed at a temperature of about 350-480° C. with a pressure of about 1-9 torr for about 15-180 sec with N₂ as the dopant source.

Referring to FIG. 3d, excess dielectric material is removed. In one embodiment, the excess dielectric material is removed by, for example, chemical mechanical polishing (CMP). Other processes for removing excess dielectric materials are also useful. The CMP removes the excess dielectric material and produces a planar surface with the substrate, forming the STIs 330 with a cap layer.

In an alternative embodiment, the cap layer comprises silicon nitride. The silicon nitride is deposited on the substrate surface by, for example, chemical vapor deposition (CVD). For example, low pressure CVD (LPCVD) can be used. Other techniques, such as PECVD, are also useful. In one embodiment, the substrate is placed into the CVD chamber to deposit the cap layer. The substrate is heated until the substrate temperature is stabilized. In doing so, the moisture in the O₃-TEOS is purged from the film. Thereafter, the cap layer is deposited on the substrate, preventing further moisture absorption by the O₃-TEOS. This enables the O₃-TEOS to maintain its stress. Preferably, the silicon nitride cap layer comprises a tensile silicon nitride cap layer. Providing a tensile silicon nitride cap layer enhances or increases the tensile stress applied to the channel.

The silicon nitride cap layer, in one embodiment, can be formed by partially filling the STI trenches with, for example, O₃-TEOS. A silicon nitride layer is then deposited over the O₃-TEOS to fill the trenches. The CMP removes excess O₃-TEOS and silicon nitride over the substrate, leaving the trenches filled with O₃-TEOS with a silicon nitride cap layer. Other techniques for forming the silicon nitride cap layer are also useful.

Next, a doped well 311 is formed. The doped well comprises first type dopants. In one embodiment, the first type dopants comprise p-type dopants which form a p-type doped well. The p-type dopants can include, for example, B. Typically, the dopant concentration of the doped well is about 1E10-1E14/cm². Conventional ion implantation techniques, such as implantation with a mask can be used to form the doped well. Other techniques are also useful. Optionally, the doped well can be formed prior to forming the STIs.

Referring to FIG. 3e, the process continues to form a transistor 340 in the active region 308 defined by the STIs. To form the transistor, gate stack layers are formed on the substrate. The gate stack layers generally comprise a polysilicon gate electrode layer over a thermal oxide gate dielectric layer. Other types of gate stack layers are also useful. The gate layers are patterned using conventional mask and etch techniques to form a gate stack 345. The gate stack can be a gate conductor which is a common gate for a plurality of transistors.

Source/drain diffusion regions 347a-b are then formed in the active region of the substrate adjacent to the gate. In one embodiment, the source/drain diffusion regions comprise dopants of second carrier type. For example, the source/drain diffusion regions comprise n-type dopants, such as P, As, Sb or a combination thereof, to form n-type diffusion regions.

Dielectric spacers 354 are formed on the sidewalls of the gate stack. The dielectric spacers, for example, comprise silicon nitride. Other types of dielectric materials are also useful to form the spacers. To form the spacers, a spacer layer is deposited on the substrate which covers the gate and substrate surface. An etch removes the horizontal components of the spacer layer, leaving spacers on the sidewalls of the gate stack.

The diffusion regions can include shallow source/drain extensions (not shown) and deep source/drain portions. The source/drain extensions can be formed before forming the sidewall spacers, while the deep source/drain portions are formed after the spacers are formed. Metal silicide contacts 358 can be formed on the gate and diffusion regions. The metal silicide contacts, for example, comprise nickel silicide contacts. Other types of metal silicide contacts are also useful. To form the metal silicide contacts, a metal layer is formed on the substrate and annealed to cause a reaction with the silicon substrate. Unreacted metal is removed, leaving the silicide contacts.

The process continues to complete fabricating the IC. For example, the process continues to form pre-metal dielectrics, interconnects, additional interconnect levels, passivation layer, dicing, assembly and packaging.

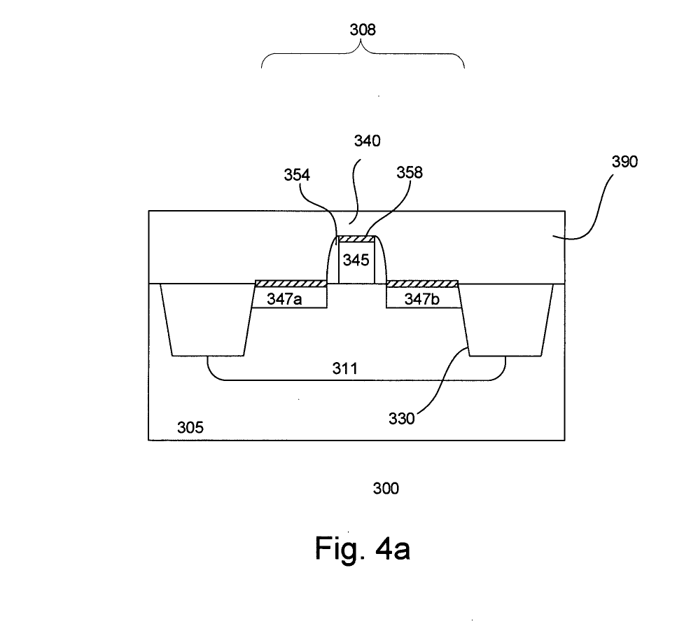

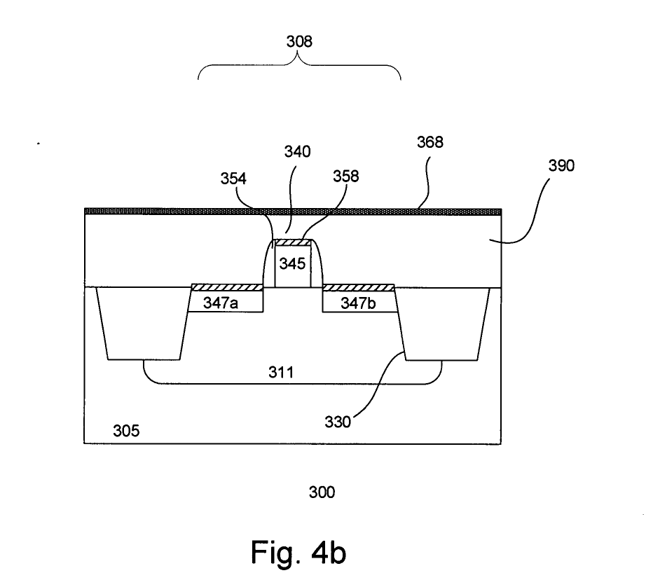

FIGS. 4a-b show a process of forming an IC 300 in accordance with another embodiment of the invention. As shown in FIG. 4a, a substrate 305 is provided. The substrate is prepared with a transistor 340 formed on an active region 308 isolated by isolation regions 330. A PMD layer 390 is formed on the substrate. The PMD layer covers the substrate and transistor. In one embodiment, the PMD layer applies the first stress. Preferably, the dielectric material comprises high tensile O₃-TEOS oxide. The O₃-TEOS oxide is formed by, for example, SACVD. In one embodiment, the O₃-TEOS oxide is formed by a conventional SACVD process. Other processes are also useful. The PMD layer can be planarized if necessary by, for example, CMP. Other methods for planarizing the PMD layer are also useful.

Referring to FIG. 4b, a PMD cap layer 368 is formed over the PMD layer. The PMD cap layer acts as a barrier to prevent moisture absorption by the PMD layer, thereby retarding tensile stress degradation thereof. In one embodiment, the PMD cap layer comprises a dielectric layer and formed by similar process as described with respect to cap layer over the STIs.

In the embodiment where RTA is employed to treat the PMD dielectric material to form the cap layer, the RTA can be integrated with the process of forming the metal silicide contacts. Typically, in forming metal silicide contacts, first and second RTA steps (RTA-1 and RTA-2) are performed. In one embodiment, RTA-2 can be integrated with the step of forming the PMD cap layer. In another embodiment, the PMD cap layer can be formed by depositing a silicon nitride layer on the PMD layer.

Optionally, a cap layer can also be provided over the STI as previously described. The process continues to complete forming the IC.

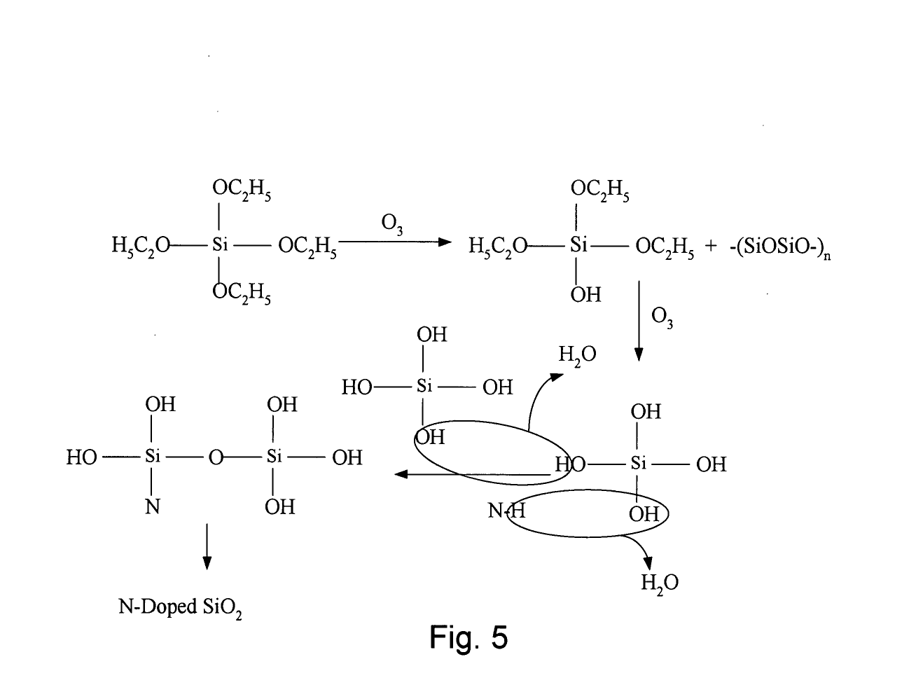

FIG. 5 shows the chemical reactions that occur during the CVD process to form the N-doped high tensile O₃-TEOS oxide film. First, O₃ and TEOS react to form silanol (Si(OH)₄). Some of the hydroxyl (OH) groups in the silanol are replaced by nitrogen (N) derived from the nitrogen source, forming N doped silanol. Thereafter, N doped O₃-TEOS oxide is formed from condensation between N doped silanol molecules. By replacing OH groups with N atoms, there are less number of OH groups. This reduces the potential for OH groups to bond with O atoms from O₃ to form H₂O (or water) molecules. As a result, the N doped O₃-TEOS has improved resistance against moisture absorption.

As described, O₃-TEOS oxide is provided in the STI and/or PMD layer to apply a tensile stress to the channel of n-type transistors to enhance carrier mobility of electrons in the channel. A cap layer is formed over the O₃-TEOS oxide in the STI and/or PMD layer, acting as a barrier to retard tensile stress degradation caused by moisture absorption. In alternative embodiments, the cap layer comprises doped SACVD O₃-TEOS or SiN.

The invention may be embodied in other specific forms without departing from the spirit or essential characteristics thereof. The foregoing embodiments, therefore, are to be considered in all respects illustrative rather than limiting the invention described herein. Scope of the invention is thus indicated by the appended claims, rather than by the foregoing description, and all changes that come within the meaning and range of equivalency of the claims are intended to be embraced therein.

What is claimed is:

1. A device comprising:
a substrate having isolation regions;
isolation material comprising a first stress in the isolation regions; and
a cap layer disposed on the isolation material, wherein the cap layer reduces degradation of the first stress.

2. The device of claim 1 further comprises a transistor disposed on an active region between isolation regions, wherein the isolation material induces stress on a channel region of the transistor.

3. The device of claim 1 wherein the isolation material comprises O₃-TEOS.

4. The device of claim 1 wherein the cap layer comprises doped O₃-TEOS.

5. The device of claim 4 wherein the cap layer comprises a dopant concentration sufficient to enable the cap layer to retard moisture absorption by the isolation material.

6. The device of claim 1 wherein the cap layer comprises N-doped O₃-TEOS.

7. The device of claim 6 wherein the cap layer comprises a dopant concentration of N sufficient to enable the cap layer to retard moisture absorption by the isolation material.

8. The IC of claim 6 wherein the cap layer comprises a dopant concentration of N of about 1E6 to 1E15 c/s.

9. The device of claim 1 wherein the cap layer comprises silicon nitride.

11. The device of claim 1 wherein the first stress comprises a tensile stress.

12. An integrated circuit (IC) comprising:
a transistor disposed on a substrate, the transistor having a channel region;
a dielectric layer disposed on the substrate over the transistor, the dielectric layer comprising a first stress; and
a cap layer disposed on the dielectric layer, wherein the cap layer reduces degradation of the first stress.

13. A method of fabricating a device comprising:
providing a substrate prepared with isolation regions, the isolation regions comprise an isolation material having a first stress;
forming a cap layer over the isolation material in the isolation regions, wherein the cap layer reduces degradation of the first stress.

14. The method of claim 13 further comprises forming a transistor in an active region separated by the isolation regions, the isolation material inducing stress on a channel of the transistor.

15. The method of claim 13 wherein the first stress comprises a tensile stress.

16. The method of claim 13 wherein the isolation material comprises O₃-TEOS.

17. The method of claim 13 wherein forming the cap layer comprises a thermal treatment in an ambient comprising dopants, the thermal treatment drives out moisture in the insulating material and causes dopants to be absorbed by the isolation material to form the cap layer.

18. The method of claim 13 wherein forming the cap layer comprises a thermal treatment in an ambient comprising N dopants, the thermal treatment drives out moisture in the insulating material and causes N to be absorbed by the isolation material to form an N-doped cap layer.

19. The method of claim 13 wherein forming the cap layer comprises forming a silicon nitride layer over the isolation material.

20. A method of fabricating an integrated circuit (IC) comprising:
providing a substrate;
forming a dielectric layer on the substrate, the dielectric layer comprises a first stress; and
forming a cap layer on the dielectric layer, wherein the cap layer reduces degradation of the first stress.

21. The method of claim 20 wherein the substrate is prepared with a transistor.

22. The method of claim 21 wherein the dielectric layer covers the transistor.

23. The method of claim 20 wherein the substrate is prepared with isolation regions.

24. The method of claim 23 wherein forming the dielectric layer comprises filling the isolation regions with the dielectric layer.
